(19) United States
(12) Patent Application Publication
(10) Pub. No.: US 2022/0113066 A1
(43) Pub. Date: Apr. 14, 2022

(54) THERMOELECTRIC POWER GENERATION WITH COMBINED HYDRONIC HEATING CAPABILITIES

(71) Applicant: David John Forseth, Clayhurst (CA)

(72) Inventor: David John Forseth, Clayhurst (CA)

(21) Appl. No.: 17/499,803

(22) Filed: Oct. 12, 2021

Related U.S. Application Data
(60) Provisional application No. 63/089,924, filed on Oct. 9, 2020.

(51) Int. Cl. F25B 21/02; F23D 14/12; F23D 14/78

(52) U.S. Cl. CPC F25B 21/02; F23D 14/78; F23D 14/12

(57) ABSTRACT

An apparatus and method for generating electricity wherein the apparatus comprises a burner operably connected to a fuel source, an energy receiving housing radially surrounding the burner having an energy receiving surface inwardly oriented towards the radian burner, at least one thermoelectric generator applied to an outer surface of the energy receiving housing and a cooler in contact with the at least one thermoelectric generator so as to position the thermoelectric generator between the cooler and the energy receiving housing. The method comprises combusting a fuel with a burner, capturing the heat from the burner with the energy receiving housing and generating electricity with a thermoelectric generator applied to the outer surface of the housing between the housing and a cooler.

### BACKGROUND

### 1. Technical Field

This disclosure related generally to electrical generation and in particular to a method and apparatus for generating electricity between the heat output of a cylindrically shaped infrared burner and a circulating cooling fluid.

### 2. Description of Related Art

Electrical generation is a common need in all parts of the world. Disadvantageously, it is sometime difficult to generate electricity in remote locations. However fuel to power a combustion engine is frequently easy to obtain at such locations. Therefore one common method of generating electricity at such remote locations is to utilize an internal combustion engine turning a generator. Disadvantageously such engines are inefficient and limited to specific fuel types.

### SUMMARY OF THE DISCLOSURE

According to a first embodiment, there is disclosed an apparatus for generating electricity comprising a burner operably connected to a fuel source, an energy receiving housing radially surrounding the burner having an energy receiving surface inwardly oriented towards the radian burner, at least one thermoelectric generator applied to an outer surface of the energy receiving housing and a cooler in contact with the at least one thermoelectric generator so as to position the thermoelectric generator between the cooler and the energy receiving housing.

The burner may comprise a radiant burner. The burner may extend along a length. The burner may be substantially tubular. The burner and the housing may extend along a common axis.

The housing may include an energy receiving interior surface. The energy receiving surface may have a dark color. The housing may have a substantially rectangular cross section. The housing may be formed of a high thermal conductivity material. The housing may be formed of a material selected from the group consisting of copper and aluminum.

The at least one thermoelectric generator may be selected to be substantially planar and positioned between relatively hot and cold surfaces. The apparatus may further comprise at least one thermoelectric generator and cooler on each side of the housing. The cooler may comprise a heat exchanger operable to transfer heat from the thermoelectric generator to a fluid. The apparatus may further comprise a closed fluid loop cooling circuit operably coupled to the cooler so as to remove heat therefrom. The apparatus may further comprise a secondary heater adapted to increase the temperature of the fluid with a secondary burner. The secondary heater may comprise a tubular radiant heater burner with a fluid filled cooling jacket therearound.

The fluid loop may include a pump. The fluid loop may include a waste heat exchanger to discharge heat from the loop to an environment. The fluid loop may include a temperature valve controlled adapted to shut off the gas supply to the burner when the temperature in the fluid loop reaches a predetermined over heat temperature.

According to a first embodiment, there is disclosed a method for generating electricity comprising combusting a fuel with a burner, capturing the heat from the burner with an energy receiving housing radially surrounding the burner and generating electricity with a thermoelectric generator applied to the outer surface of the housing between the housing and a cooler.

Other aspects and features of the present disclosure will become apparent to those ordinarily skilled in the art upon review of the following description of specific embodiments in conjunction with the accompanying figures.

### BRIEF DESCRIPTION OF THE DRAWINGS

The accompanying drawings constitute part of the disclosure. Each drawing illustrates exemplary aspects wherein similar characters of reference denote corresponding parts in each view,

FIG. 1 is a perspective view of an apparatus for generating electricity according to a first exemplary embodiment of the present disclosure.

FIG. 2 is a detailed perspective view of the burner assembly of the apparatus of FIG. 1.

FIG. 3 is a detailed perspective view of the burner assembly of the apparatus of FIG. 1.

FIG. 4 is a cross sectional view of the burner assembly of the apparatus of FIG. 1 as taken along the line 4-4 of FIG. 3.

FIG. 5 is a schematic diagram of the cooling circuit of the apparatus of FIG. 1.

FIG. 6 is a perspective view of a secondary heater for use in the apparatus of FIG. 1 according to a further embodiment.

### DETAILED DESCRIPTION

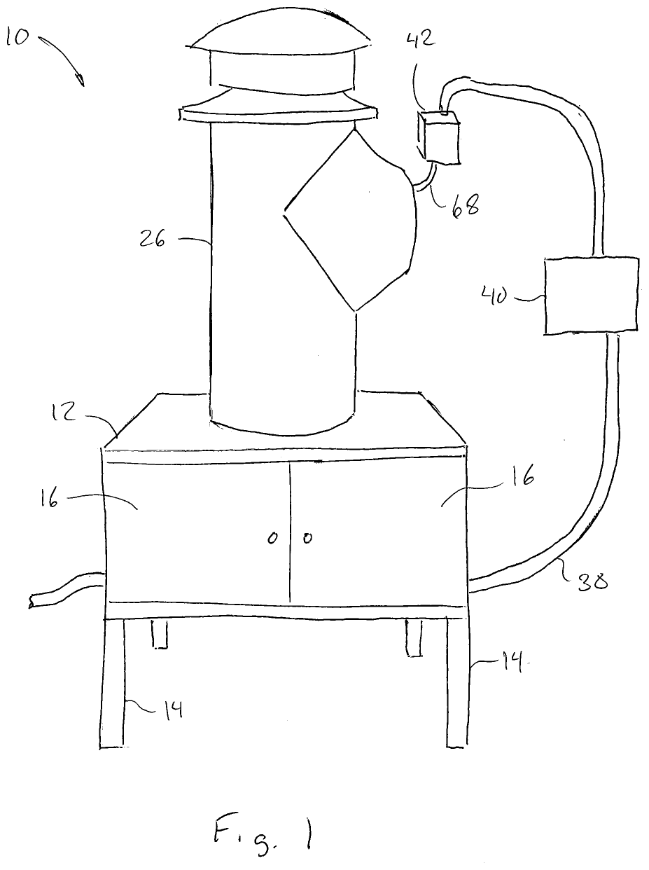

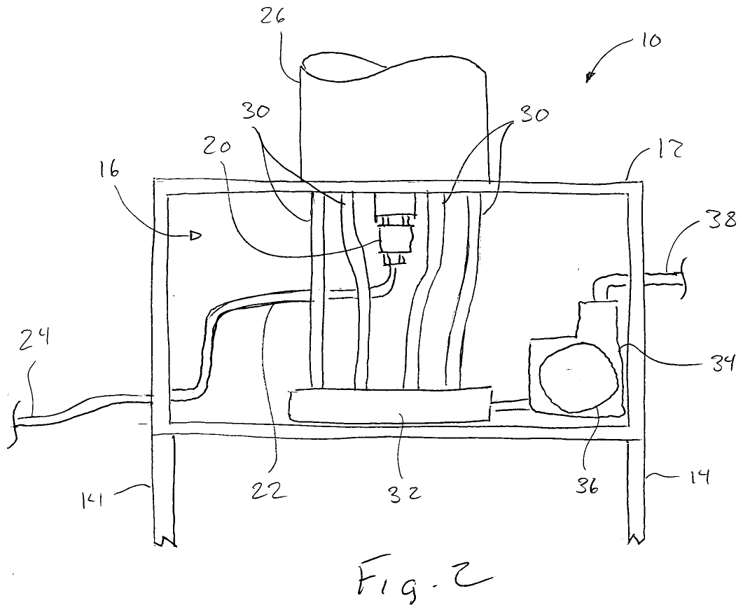

Aspects of the present disclosure are now described with reference to exemplary apparatuses, methods and systems. Referring to FIG. 1, an exemplary apparatus for generating electricity according to a first embodiment is shown generally at 10. The apparatus 10 comprises a cabinet 12 containing a burner 20, such as an infrared burner, (illustrated in FIG. 2) exhausting through a thermal absorbing exhaust stack 52. The apparatus 10 further includes at least one thermoelectric generator 70 arranged in contact with an outlet of the burner and a cooling heat exchanger to generate electricity from the temperature difference therebetween as will be more fully described below.

As illustrated in FIGS. 1 and 2, the cabinet 12 may be substantially rectangular although it will be appreciated that other shapes may also be useful. The cabinet 12 may include legs 14 or any other means to support the cabinet at a desired height or location and doors 16 openable to provide access to an interior thereof. The doors 16 are omitted from FIG. 2 to illustrate an interior 16 of the cabinet and components located therein.

As illustrated in FIG. 2, the apparatus 10 includes in the interior 16 of the cabinet 12, a burner 20 connected to a fuel supply line 22. The fuel supply line 22 may include a pressure regulator, valve or other fuel supply components (not illustrated) as are commonly known and may extend to an external line 24 which connects to a fuel supply including a temperature activated safety shut off valve. The fuel supply may be of any known type operable to store and supply a combustible fuel, including without limitation, propane, natural gas, diesel or other hydrocarbons. The apparatus 10 includes a flue 26 extending from the cabinet 12 in a substantially upward direction so as to receive and direct the exhaust gasses and heat away from the burner 20 as is commonly known.

The apparatus also includes a plurality of return water lines 30 extending from thermoelectric cooling heat exchangers from the interior of flue 26 to a common collection manifold 32 in the cabinet 12. The collection manifold 32 is in fluidic communication with a pump 34 which is powered by an electric motor 36. The pump 34 is furthermore connected to a cooling loop 38. As illustrated in FIG. 1, the cooling loop 38 includes a fluid conduit extending from the pump 34 to a waste heat exchanger 40 and a subsequent reservoir 42. It will be appreciated that any known style of waste heat exchanger 40 may be utilized, including fan coil units tube and shell or the like. The reservoir supplies the cooled fluid to the cooling heat exchanger 60 as will be more fully described below. The cooling heat exchanger 60 or any associated fans may also include an optional bypass or temperature control so as to maintain the cooling fluid within a desired temperature range. Such fans may also be powered by the electricity generated by the thermoelectric generators. The waste heat exchanger 40 may be omitted by including greater length of conduit that is passed through a body of snow, ground, water or the like to cool the fluid passing therethrough or may optionally be used for heating purposes.

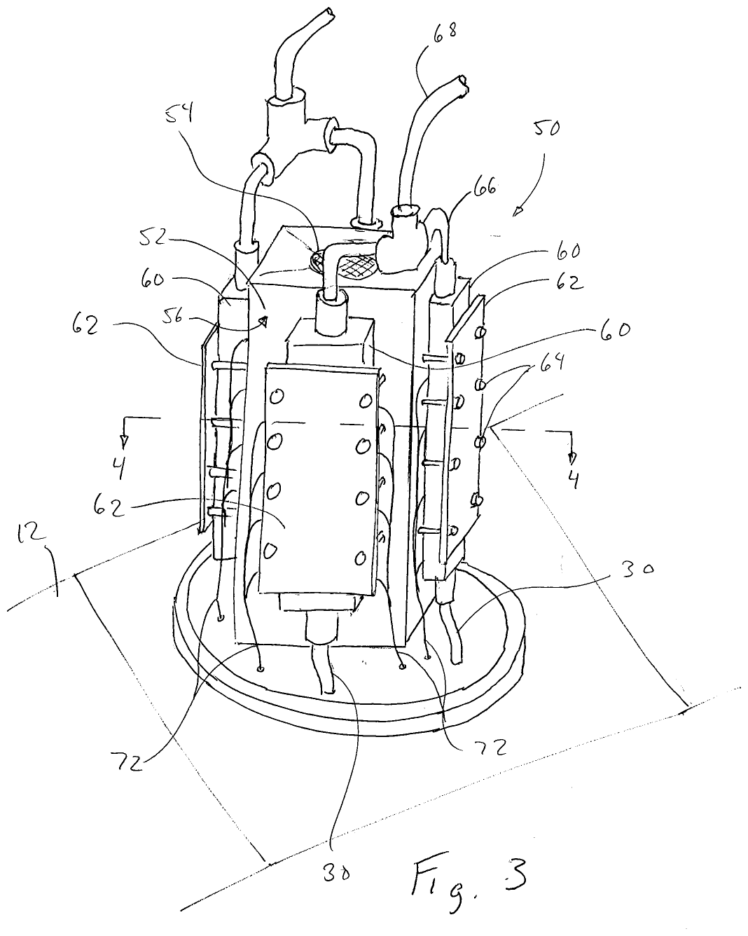

Turning now to FIG. 3, a view of the exhaust assembly 50 is illustrated with the flue shrouding 26 removed. The exhaust assembly 50 includes a thermal conductive exhaust stack 52 extending upwards from the cabinet 12. The exhaust stack 52 includes an open interior that is in communication with the infrared burner 20 so as to receive the radiant heat and exhaust gasses therefrom and an exhaust opening 54 at a top end thereof. As illustrated, the exhaust stack 52 may have a square cross section, although it will be appreciated that other shapes may be useful as well, such as, by way of non-limiting example, rectangular, triangular, octagonal or round. The exhaust stack 52 includes an outer surface 56 onto which supplies the heating for the thermoelectric modules and cooling heat exchangers 60 are secured. As illustrated in FIG. 3, the cooling heat exchangers 60 may be secured to the exhaust stack 52 by bolts 64 or other fasteners although it will be appreciated that other securing means may also be utilized to retain thermoelectric modules and the cooling heat exchangers 60 to the outer surface 56 of the exhaust stack 52. Each of the cooling heat exchangers 60 is formed of a thermally conductive material, such as, by way of non-limiting example, copper or aluminium and includes a supply conduit 66 supplying a fluid thereto and a return line 30 as set out above. The supply conduits 66 may be connected by couplers or the like to form a common supply line 68 in fluidic communication with the reservoir 42 a set out above.

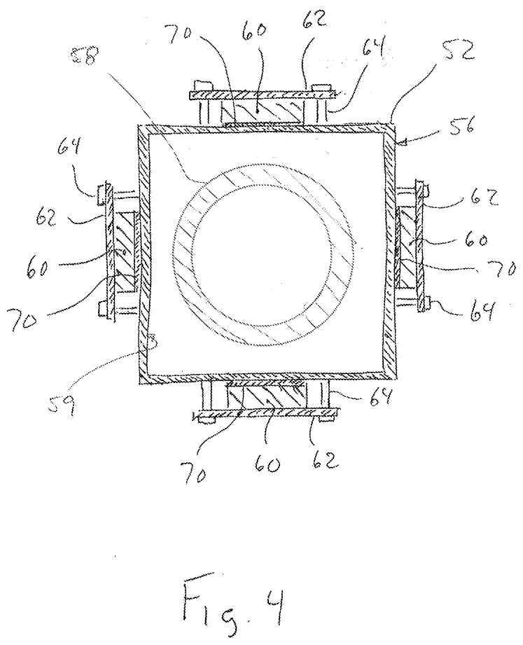

Turning now to FIG. 4, a cross sectional view across the exhaust stack 52 is illustrated with a cooling heat exchangers 60 arranged around for sides thereof. As illustrated in FIG. 4, the exhaust stack 52 includes an emitter 58 formed of a radiant energy emitting material, such as by way of non-limiting example, expanded metal or mesh. The emitter 58 surrounds the flame output from the burner 20 so as to glow or emit radiant energy. Alternatively, the burner 20 and emitter 58 may comprise an infrared radiant burner as are known. It will be appreciated that the emitter may extend substantially the height of the exhaust stack so as to radiate energy outwards in a substantially uniform manner with very little emissions. The exhaust stack 52 is formed of a thermally conductive material, such as, by way of non-limiting example, copper or aluminium and should be advantageously include a high temperature resistant dark coloured paint, including without limitation, black and dark shades of grey, brown, blue, green, red and purple applied to the interior surface 59 thereof to aid in heat absorption from the emitter 58.

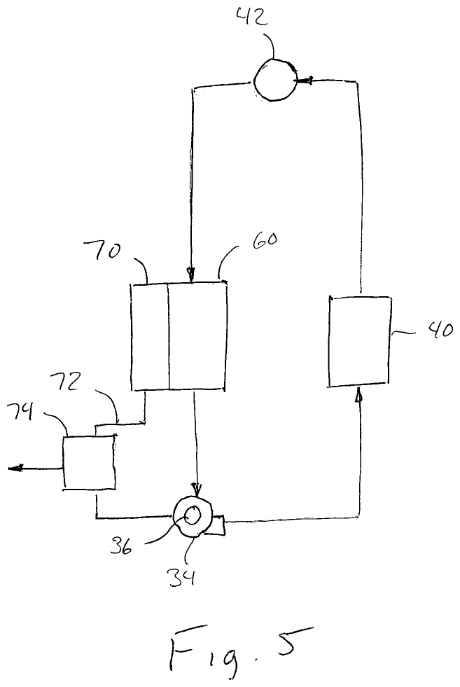

Furthermore, each of the cooling heat exchangers 60 includes thermoelectric generator modules 70 sandwiched between the cooling heat exchanger and the outer surface 56 of the exhaust stack 52. In operation, it will be appreciated that while the burner 20 is in operation, the exhaust stack 52 will be hot due to the absorbed infrared energy and exhaust gasses from the burner 20 and the cooling heat exchanger will be maintained cool due to the cooling loop 30 as set out above. The thermoelectric generator modules 70 will therefore be operable to generate an electric current due to the temperature difference thereacross. It will be appreciated that any thermoelectric generator may be utilized in the present apparatus and that in particular solid state planar devices capable of withstanding the temperature of the exhaust gasses are particularly useful. Each of the thermoelectric generators 70 is electrically coupled through wiring 72 to a collection point such as a controller or battery 74 for use thereafter. With reference to FIG. 5, the electric motor 36 may also be operable coupled to the controller so as to receive power from the thermoelectric generator. It will also be appreciated that more than one electric generator 70 may also be utilized and wired to each other in parallel or series.

In operation, the controller 74 may be connected to the valves operating the burner as is known to control the operation of the burner and the cooling loop. The controller may initially activate the burner to begin burning. The output of the burner 20 and therefore the heat radiated by the emitter 58 will be controlled by a valve to the burner. Optionally, such valves may be located in the reservoir 42 so as to monitor the temperature of the cooling fluid so to ensure the system does not overheat by shutting down when a predetermined temperature is reached. Once the emitter 58 begins radiating infrared energy to the exhaust stack 52 which is absorbed thereby, a temperature difference will be created between the exhaust stack 52 and the heat exchanger 60. The temperature difference between the exhaust stack 52 and the cooling heat exchanger 60 will generate electricity at each of the thermoelectric modules and generators for collection by the controller and/or electric motor 32. The pump may begin operation immediately upon the thermoelectric generators 70 producing electricity so as to cool the heat exchangers 60. Any surplus electricity generated by the apparatus may then be provided for external use by a user.

It will be appreciated that any combustion fuel may be utilized in the present apparatus as is available. It will also be appreciated that any desired cooling fluid may also be utilized, including without limitation, water, glycol or refrigerants.

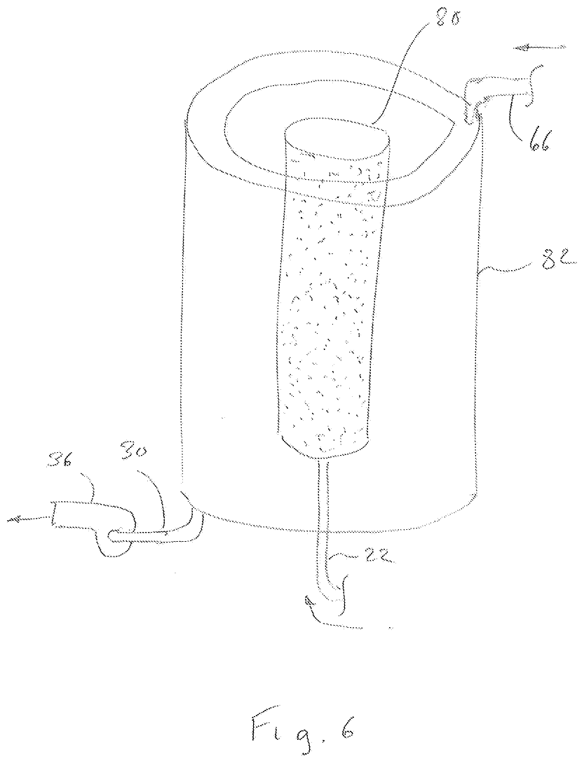

Although a single burner and set of thermoelectric generators are illustrated in FIGS. 1-5, it will be appreciated that a plurality of burners arranged in parallel or series so as to provide an energy source to a common or a plurality of receiving surfaces. Such secondary burners may also optionally be utilized to primarily provide additional heat to the fluid wherein the fluid may thereafter be utilized as a heating source for use in domestic or space heating. In particular, as illustrated in FIG. 6, such a secondary heater may comprise a tubular radiant heater 80 surrounded by a fluid filled tank 82 adapted to receive the energy therefrom. The fluid tank 82 may be formed of a heat absorbent material and finish as set out above and may be located in line within the fluid loop. The gas flow to the secondary burner 80 may be controlled by a thermal shut off switch as are known in either the tank 82 or within the discharge line therefrom.

While specific embodiments have been described and illustrated, such embodiments should be considered illustrative only and not as limiting the disclosure as construed in accordance with the accompanying claims.

What is claimed is:

1. An apparatus for generating electricity comprising:
a burner operably connected to a fuel source;
an energy receiving housing radially surrounding the burner having an energy receiving surface inwardly oriented towards the radian burner;
at least one thermoelectric generator applied to an outer surface of the energy receiving housing; and
a cooler in contact with the at least one thermoelectric generator so as to position the thermoelectric generator between the cooler and the energy receiving housing.

2. The apparatus of claim 1 wherein the burner comprises a radiant burner.

3. The apparatus of claim 2 wherein the burner extends along a length.

4. The apparatus of claim 3 wherein the burner is substantially tubular.

5. The apparatus of claim 4 wherein the burner and the housing extend along a common axis.

6. The apparatus of claim 1 wherein the housing includes an energy receiving interior surface.

7. The apparatus of claim 6 wherein the energy receiving surface has a dark color.

8. The apparatus of claim 6 wherein the housing has a substantially rectangular cross section.

9. The apparatus of claim 6 wherein the housing is formed of a high thermal conductivity material.

10. The apparatus of claim 9 wherein the housing is formed of a material selected from the group consisting of copper and aluminum.

11. The apparatus of claim 1 wherein the at least one thermoelectric generator is selected to be substantially planar and positioned between relatively hot and cold surfaces.

12. The apparatus of claim 1 further comprising at least one thermoelectric generator and cooler on each side of the housing.

13. The apparatus of claim 1 wherein the cooler comprises a heat exchanger operable to transfer heat from the thermoelectric generator to a fluid.

14. The apparatus of claim 13 further comprising a closed fluid loop cooling circuit operably coupled to the cooler so as to remove heat therefrom.

15. The apparatus of claim 14 further comprising a secondary heater adapted to increase the temperature of the fluid with a secondary burner.

16. The apparatus of claim 15 wherein said secondary heater comprises a tubular radiant heater burner with a fluid filled cooling jacket therearound.

17. The apparatus of claim 14 wherein the fluid loop includes a pump.

18. The apparatus of claim 14 wherein the fluid loop includes a waste heat exchanger to discharge heat from the loop to an environment.

19. The apparatus of claim 14 wherein the fluid loop includes a temperature valve controlled adapted to shut off the gas supply to the burner when the temperature in the fluid loop reaches a predetermined over heat temperature.

20. A method for generating electricity comprising:
combusting a fuel with a burner;
capturing the heat from the burner with an energy receiving housing radially surrounding the burner; and
generating electricity with a thermoelectric generator applied to the outer surface of the housing between the housing and a cooler.
